(19) United States
(12) Patent Application Publication
(10) Pub. No.: US 2026/0165133 A1
(43) Pub. Date: Jun. 11, 2026

(54) SEMICONDUCTOR PACKAGE AND METHOD FORMING THE SAME

(71) Applicant: Taiwan Semiconductor Manufacturing Co., Ltd., Hsinchu (TW)

(72) Inventors: Hung-Chi Wu, Taipei City (TW); Chien Hao Hsu, Zhubei City (TW); Kuo-Chin Chang, Chiayi City (TW); Kathy Wei Yan, Hsinchu (TW); Mirng-Ji Lii, Sinpu Township (TW)

(21) Appl. No.: 18/969,651

(22) Filed: Dec. 5, 2024

(51) Int. Cl. H01L 23/58; H01L 21/768; H01L 23/00

(52) U.S. Cl. CPC H10W 42/00; H10W 20/084; H10W 42/121; H10W 72/0198; H10W 72/29; H10W 74/15; H10W 90/724; H10W 90/734

(57) ABSTRACT

A semiconductor package and the method of forming are provided. The semiconductor package may include a package component bonded to a package substrate. The package component may include a semiconductor substrate, a plurality of electrical devices on the substrate, a plurality of dielectric layers over the substrate and the electrical devices, a first passivation layer on the plurality of dielectric layers, and a seal ring structure. The seal ring structure may comprise a first ring structure in the first passivation layer and a second ring structure in the plurality of dielectric layers. The first ring structure may encircle the plurality of electrical devices in a top-down view and comprise a plurality of bends adjacent a first corner of the package component in the top-down view. The second ring structure may be in contact with the first ring structure and encircle the plurality of electrical devices in the top-down view.

### BACKGROUND

In wafer-level packaging technology, seal ring structures are formed in the peripheral region of the device dies, and used to provide protection to the circuits encircled by the seal rings. The seal ring may prevent moisture from penetrating into the device dies to degrade the circuits encircled by the seal rings. The seal rings may extend into multiple layers of integrated circuit structure such as low-k dielectric layers and the overlaying passivation layers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2A, 2B, 2C, 2D, 2E, 2F, 2G, 3, 4, 5, 6, 7, 8A, 8B, 8C, 8D, 9, and 10 illustrate cross-sectional views and top-down views of intermediate steps in the formation of a semiconductor package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor package including a seal ring structure and the method of forming the same are provided. In accordance with some embodiments, the semiconductor package may comprise a package component having a plurality of electrical devices and a plurality of conductive features in a plurality of dielectric layers. Two or more passivation layers and a protective layer are on the plurality of dielectric layers. The seal ring structure may extend in the plurality of dielectric layers and the passivation layers, and encircle the plurality of electrical devices and the plurality of conductive features in a top-down view. A portion of the seal ring structure in the passivation layers may have various configurations. The portion of the seal ring structure may comprises a plurality of bends adjacent corners of the passivation layers. The portion of the seal ring structure may be a continuous structure or a fragmented structure with linear or non-linear breaks. Due to the various configurations of the portion of the seal ring structure, the stress in the passivation layers and the protective layer may be reduced. As a result, the formation and/or propagation of cracks and/or delamination in the passivation layers and the protective layer may be prevented or reduced, thereby improving the performance and reliability of the semiconductor package.

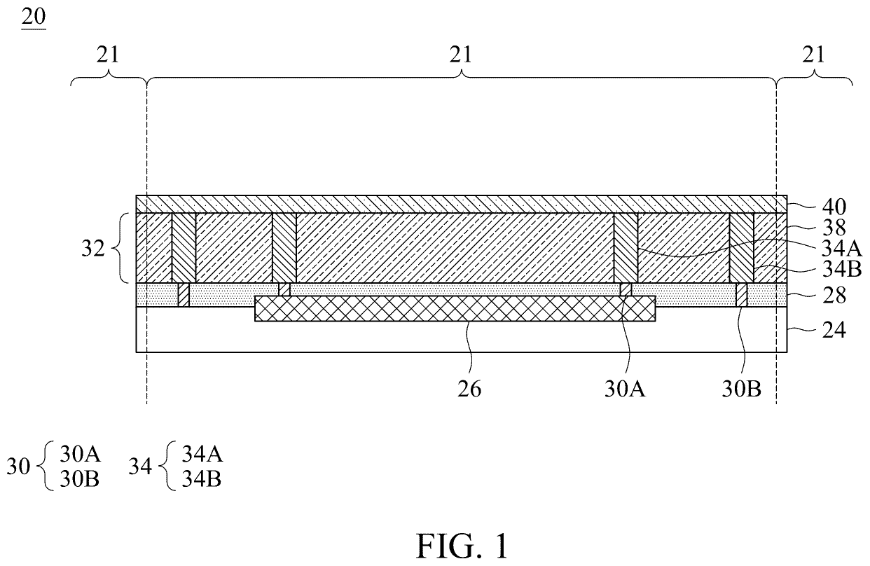

FIG. 1 illustrates a cross-sectional view of a package component 20. The package component 20 may be a device wafer including active devices and/or passive devices, which may be shown as devices 26. The package component 20 may comprise various regions 21, each of which may comprises the corresponding the devices 26. One region 21 with structural details is shown in FIG. 1 for illustrative purposes. Various features may be formed on the package component 20 and the package component 20 along with the various features may be singulated into a plurality of smaller package components in subsequent processes, each of which may correspond to a region 21.

The package component 20 may include a semiconductor substrate 24. The semiconductor substrate 24 may comprise crystalline silicon, crystalline germanium, silicon germanium, carbon-doped silicon, or a III-V compound semiconductor such as GaAsP, AlInAs, AlGaAs, GaInAs, GaInP, GaInAsP, or the like. The semiconductor substrate 24 may also be a bulk semiconductor substrate or a Semiconductor-On-Insulator (SOI) substrate. Shallow Trench Isolation (STI) regions (not separately illustrated) may be formed in the semiconductor substrate 24 to isolate the active regions in the semiconductor substrate 24. The package component 20 may include the devices 26 on a top surface of the semiconductor substrate 24. The devices 26 may be electrically devices, such as transistors, resistors, capacitors, diodes, and the like.

Inter-Layer Dielectric (ILD) 28 may be over the semiconductor substrate 24 and fill the spaces between the gate stacks of transistors (not separately illustrated) in the devices 26. The ILD 28 may comprise Phospho Silicate Glass (PSG), Boro Silicate Glass (BSG), Boron-doped Phospho Silicate Glass (BPSG), Fluorine-doped Silicate Glass (FSG), silicon oxide, silicon nitride, silicon oxynitride, low-k dielectric materials, or the like. The ILD 28 may be formed by a suitable deposition process, such as Chemical Vapor Deposition (CVD), Atomic Layer Deposition (ALD), or the like.

Contact plugs 30 may be in the ILD 28. The contact plugs 30 may include active contact plugs 30A and inactive contact plugs 30B. The active contact plugs 30A may be physically and electrically connected to the devices 26. The inactive contact plugs 30B may be electrically isolated from the devices 26. In some embodiments, the inactive contact plugs 30B extend though the ILD 28 and contact the semiconductor substrate 24. The contact plugs 30 may comprise conductive material(s), such as tungsten, aluminum, copper, titanium, tantalum, titanium nitride, tantalum nitride, alloys therefore, and/or multi-layers thereof. The contact plugs 30 may be formed by forming openings in the ILD 28, filling conductive material(s) into the openings by plating or the like, and performing a planarization process, such as Chemical Mechanical Polishing (CMP) or the like, to level top surfaces of the contact plugs 30 and the ILD 28.

Dielectric layers 38 may be over the ILD 28 and the contact plugs 30. The dielectric layers 38 may be referred to as Inter-metal Dielectrics (IMDs). Conductive features 34 may be in the dielectric layers 38. The conductive features 34 may include a plurality of metal lines (not separately illustrated) interconnected by a plurality of metal vias 36 (not separately illustrated). The conductive features 34 may include a metal line level with a top surface of the dielectric layers 38, and such metal line may be referred to as a top conductive feature. The conductive features 34 may include active conductive features 34A and inactive conductive features 34B. The active conductive features 34A may be physically and electrically connected to the active contact plugs 30A. The inactive conductive features 34B may be physically and electrically connected to the inactive contact plugs 30B, and may be electrically isolated from the devices 26. The dielectric layers 38 and the conductive features 34 may be collectively referred to as an interconnect structure 32.

The conductive features 34 may be formed of copper, copper alloys, or the like. The conductive features 34 may be formed by single damascene processes and/or dual damascene processes. The dielectric layers 38 may be formed of low-k dielectric materials. The dielectric constants (k values) of the low-k dielectric materials may be lower than about 3.0. The dielectric layers 38 may be formed by a suitable deposition process, such as CVD, ALD, or the like.

A first passivation layer 40 may be over the interconnect structure 32. The first passivation layer 40 may comprise a dielectric material, such as silicon nitride, silicon oxide, silicon oxynitride, silicon oxycarbide, or the like. The first passivation layer 40 may be formed by a suitable deposition process, such as CVD, ALD, or the like.

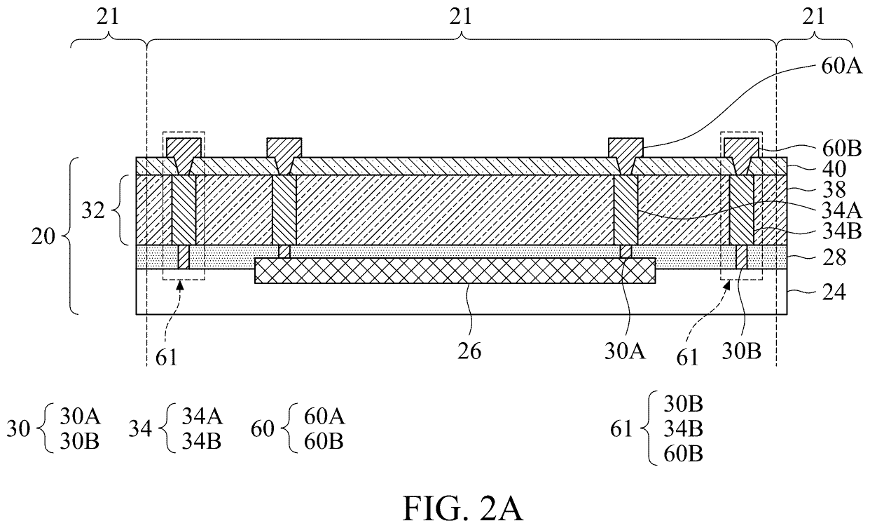

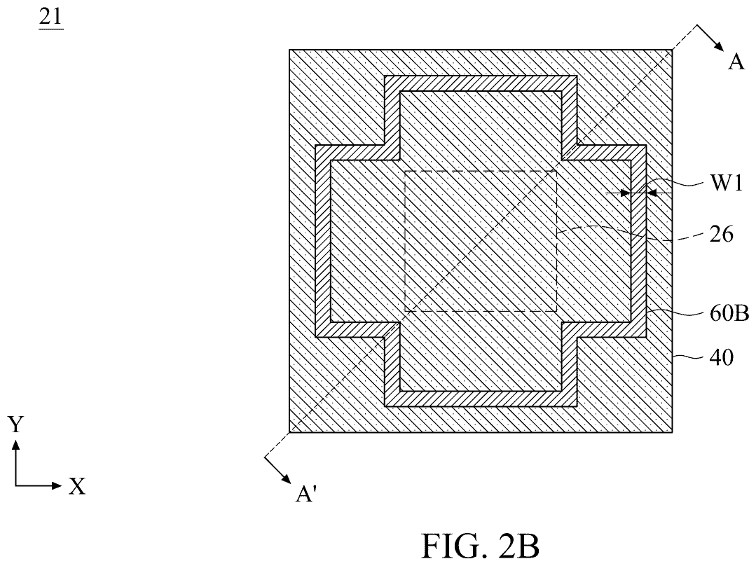

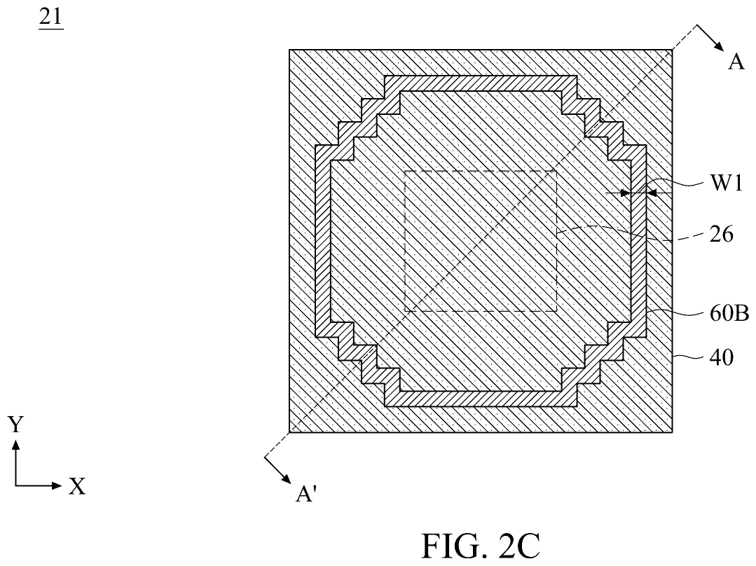

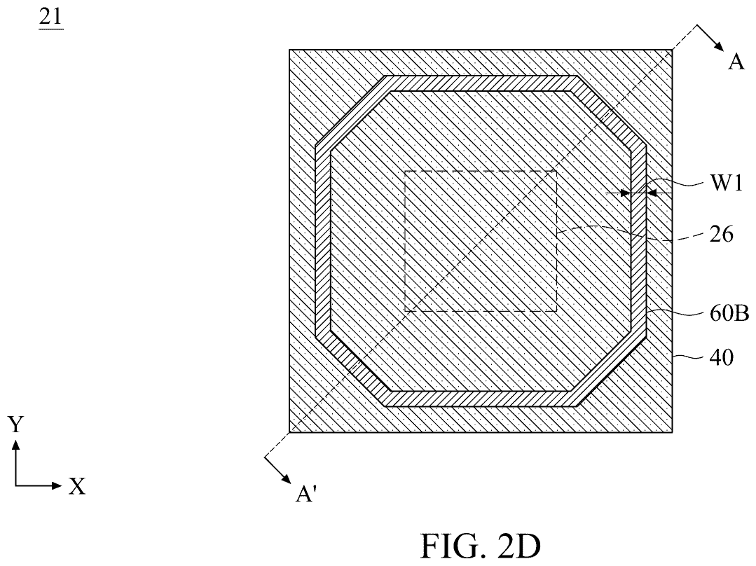

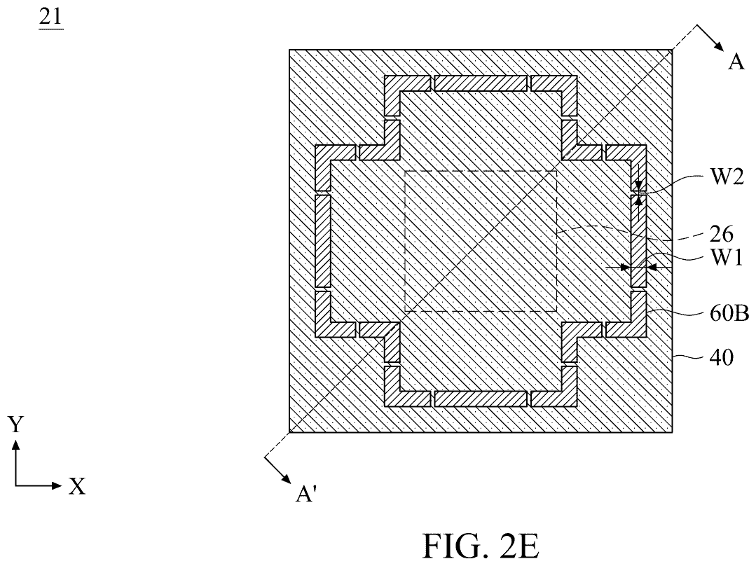

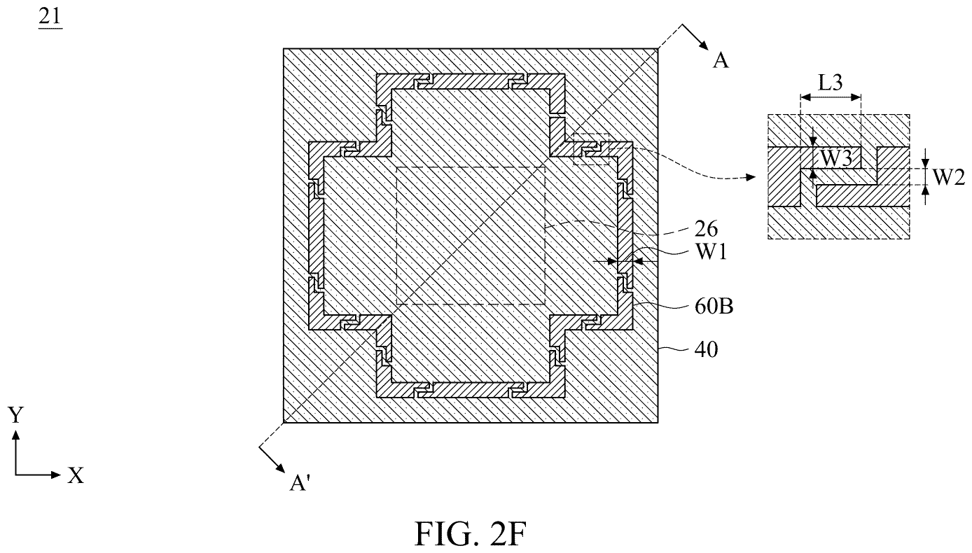

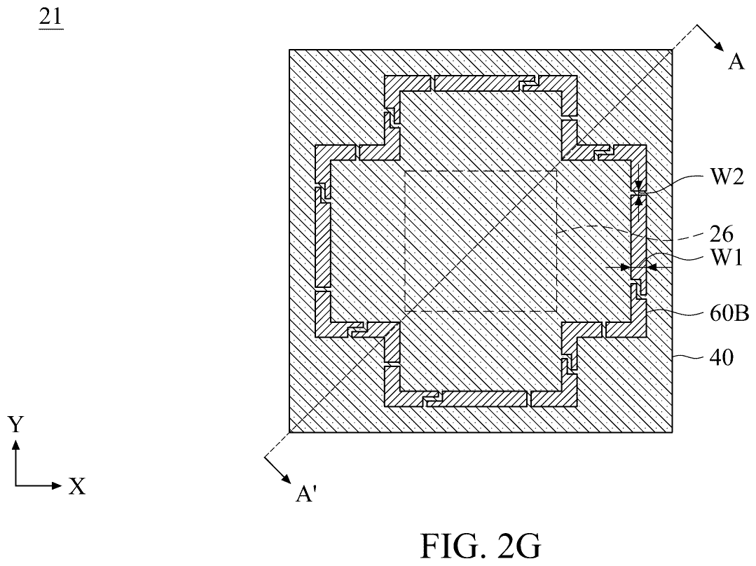

In FIGS. 2A and 2B, Redistribution Lines (RDLs) 60 are formed in and on the first passivation layer 40. FIG. 2A shows a cross-sectional view and FIG. 2B shows a top-down view. The cross-sectional view in FIG. 2A may be obtained along reference cross-section AA′ in the top-down view in FIG. 2B. One region 21 is shown in FIG. 2B for illustrative purposes. The RDLs 60 may include lower portions extending through the first passivation layer 40 and may be physically and electrically connected to the conductive features 34. The RDLs 60 may include upper portions extending on the first passivation layer 40. Bottom surfaces of the upper portions of the RDLs 60 may be in contact with the first passivation layer 40. The RDLs 60 may include active RDLs 60A and inactive conductive features 60B. The active RDLs 60A may be physically and electrically connected to the active conductive features 34A. The inactive conductive features 60B may be physically and electrically connected to the inactive conductive features 34B, and may be electrically isolated from the devices 26. The inactive contact plugs 30B, the inactive conductive features 34B, and the inactive conductive features 60B may be collectively referred to as a seal ring structure 61.

Within the region 21, the inactive conductive feature 60B may be a ring structure and encircle the devices 26 and the active RDLs 60A in the top-down view. The devices 26 are shown in dashed lines and the active RDLs 60A are omitted in FIG. 2B for illustrative purposes. The inactive conductive feature 60B may comprise two or more bends adjacent each corner of the first passivation layer 40. The inactive conductive feature 60B may comprises linear segments extending along edges of the first passivation layer 40 and corner segments adjacent the corners of the first passivation layer 40. Each corner segment of the inactive conductive feature 60B may connect two neighboring linear segments of the inactive conductive feature 60B that extend along intersecting edges of the first passivation layer 40. Each corner segment of the inactive conductive feature 60B may form non-straight angles with the linear segments of the inactive conductive feature 60B connected to the corner segment of the inactive conductive feature 60B. Corner regions of the first passivation layer 40 may be free of the inactive conductive feature 60B, which may reduce stress in the corner regions of the first passivation layer 40 and the corner regions of the subsequently formed layers over the first passivation layer 40. As a result, formation of cracks and/or delamination in the first passivation layer 40 and the subsequently formed layers over the first passivation layer 40 may be prevented or reduced as described in greater details below. The inactive conductive feature 34B underneath the inactive conductive feature 60B may have a similar shape as the inactive conductive feature 60B in the top-down view.

In the embodiments shown in FIG. 2B, the inactive conductive feature 60B may be a continuous ring structure and have a rectangular shape with four inverted corners (e.g., notched corners with right angles) adjacent the four corners of the first passivation layer 40. The inactive conductive feature 60B may comprise three bends adjacent each corner of the first passivation layer 40. The corner segments of the inactive conductive feature 60B may have a shape of an “L” in the top-down view. Each corner segment of the inactive conductive feature 60B may form right angles with the linear segments of the inactive conductive feature 60B connected to the corner segment of the inactive conductive feature 60B. The inactive conductive feature 60B may have a width W1 in range from about 3.6 μm to about 9.9 μm in the top-down view.

The RDLs 60 may be formed by a series of processes, which are provided in the following as an example. First, the first passivation layer 40 may be patterned by a suitable a photolithography process to form openings which may exposed the top conductive features of the conductive features 34. Then a seed layer (not separately illustrated) may be formed on the first passivation layer 40 and in the openings in the first passivation layer 40 by a suitable deposition process, such as PVD, CVD, or the like. The seed layer may comprise a titanium layer and a copper layer over the titanium layer. Next, a patterned mask may be formed on the seed layer. The patterned mask may have openings that expose portions of the seed layer. The patterned mask may comprise photoresist or the like. A conductive material may be then formed in the openings in the patterned mask and on the exposed portions of the seed layer by a suitable plating process, such as electrochemical plating, electroless plating, or the like. The conductive material may comprise, copper, aluminum, titanium, nickel, tungsten, or the like, or alloys thereof. Next, the patterned mask may be removed by a suitable ashing process or the like and portions of the seed layer that are not covered by the conductive material may also be removed by a suitable etching process. The conductive material and the underlying portions of the seed layer may be collectively referred to as the RDLs 60.

FIG. 2C illustrates a region 21 similar to the one shown in FIG. 2B, in accordance with some embodiments, where like numerals refer to like features formed by like processes. In the embodiments shown in FIG. 2C, the inactive conductive feature 60B may be a continuous ring structure and have an octagonal shape with linear (e.g., straight) segments and stair-shaped (e.g., bending) corner segments arranged in an alternating pattern. The inactive conductive feature 60B may comprise more than three bends (e.g., seven bends) adjacent each corner of the first passivation layer 40. Each corner segment of the inactive conductive feature 60B may form right angles with the linear segments of the inactive conductive feature 60B connected to the corner segment of the inactive conductive feature 60B.

FIG. 2D illustrates a region 21 similar to the one shown in FIG. 2B, in accordance with some embodiments, where like numerals refer to like features formed by like processes. In the embodiments shown in FIG. 2D, the inactive conductive feature 60B may be a continuous ring structure and have an octagonal shape. The inactive conductive feature 60B may comprise two bends adjacent each corner of the first passivation layer 40. Each corner segment of the inactive conductive feature 60B may form obtuse angles with the linear segments of the inactive conductive feature 60B connected to the corner segment of the inactive conductive feature 60B.

FIGS. 2E through 2G each illustrates a region 21 similar to the one shown in FIG. 2B, in accordance with some embodiments, where like numerals refer to like features formed by like processes. In the embodiments shown in FIGS. 2E through 2G, the inactive conductive features 60B may be fragmented ring structures with breaks extending though the inactive conductive features 60B in the top-down view. The breaks may reduce stress in neighboring regions of the first passivation layer 40 and the neighboring regions of the subsequently formed layers over the first passivation layer 40. As a result, the formation of cracks and/or delamination in the first passivation layer 40 and the subsequently formed layers over the first passivation layer 40 may be prevented or reduced as described in greater details below. Lower portions of the breaks in the lower portions of the inactive conductive features 60B may be filled with the material of the first passivation layer 40. In some embodiments, the inactive conductive features 60B with shapes similar to the ones shown in FIGS. 2C and 2D also have breaks similar to the ones shown in FIGS. 2E through 2G.

In the embodiments shown in FIG. 2E, the inactive conductive features 60B may be fragmented ring structures with linear (e.g., straight) breaks. The linear breaks may have a width W2 in a range from about 1.8 μm to about 2.7 μm. Such a range for the width W2 may maintain the mechanical integrity of the seal ring structure 61 and lead to sufficient reduction of stress in the first passivation layer 40 and the subsequently formed layers over the first passivation layer 40.

In the embodiments shown in FIG. 2F, the inactive conductive features 60B may be fragmented ring structures with non-linear (e.g., bending) breaks. The non-linear breaks may comprise to two bends and may have a shape of a “Z”. The non-linear breaks may have the width W2. Portions of the inactive conductive features 60B in FIG. 2F are magnified to show more structural details. The non-linear breaks with such a shape may prevent or reduce propagation of cracks in the first passivation layer 40 and the subsequently formed layer over the first passivation layer 40 that covers the upper portions of the inactive RDL. Protrusions of the inactive conductive features 60B adjacent the non-linear breaks may have a width W3 and a length L3. The width W3 may be along a same direction as the width W1 of the inactive conductive features 60B and may be greater than about 10% of the width W1. The length L3 may be along an edge of the inactive conductive feature 60B. A ratio of the length L3 to the width W2 of the non-linear breaks may be in a range between about 3 and about 10. Such ranges for the width W3 and the length L3 may maintain the mechanical integrity of the seal ring structure 61 and lead to effective prevention or reduction of the propagation of cracks in the first passivation layer 40 and the subsequently formed layer over the first passivation layer 40 that covers the upper portions of the inactive RDL.

In the embodiments shown in FIG. 2G, the inactive conductive features 60B may be fragmented ring structures with both linear breaks and non-linear breaks. The linear breaks in FIG. 2G may be same or similar to the linear breaks in FIG. 2E. The non-linear breaks in FIG. 2G may be same or similar to the non-linear breaks in FIG. 2F. The quantities, locations, arrangements, shapes, and sizes of the breaks shown in FIGS. 2E through 2G are provided as examples. Other quantities, locations, arrangements, shapes, and sizes of the breaks are also contemplated.

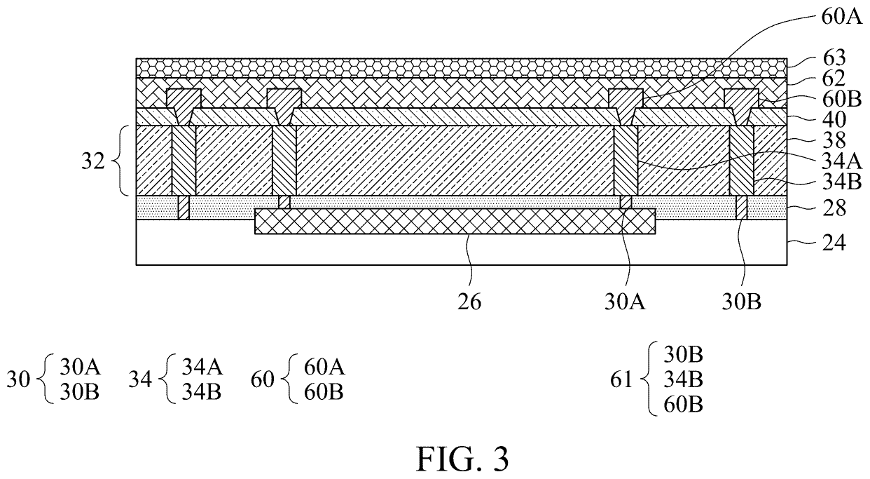

In FIG. 3, a second passivation layer 62 is formed on the RDLs 60 and the first passivation layer 40 and a third passivation layer 63 is formed on the second passivation layer 62. The second passivation layer 62 may completely cover top surfaces and sidewalls of the upper portions of the RDLs 60 on the first passivation layer 40. In the embodiments where the inactive conductive features 60B are fragmented ring structures with breaks, upper portions of the breaks in the upper portions of the inactive conductive features 60B may be filled with a material of the second passivation layer 62. The second passivation layer 62 and the third passivation layer 63 may comprise inorganic dielectric materials, such as silicon nitride, silicon oxide, silicon oxynitride, silicon oxycarbide, or the like. In some embodiments, the material of the second passivation layer 62 is different from the material of the first passivation layer 40 and the material of the second passivation layer 62 is different from the material of the third passivation layer 63, wherein the first passivation layer 40 comprises silicon nitride, the second passivation layer 62 comprises silicon oxide, and the third passivation layer 63 comprises silicon nitride. The second passivation layer 62 and the third passivation layer 63 may be formed sequentially by suitable deposition processes, such as ALD, CVD, or the like. After the deposition process of the second passivation layer 62 and before the deposition process of the third passivation layer 63, a planarization process, such as CMP or the like, may be performed to level a top surface of the second passivation layer 62.

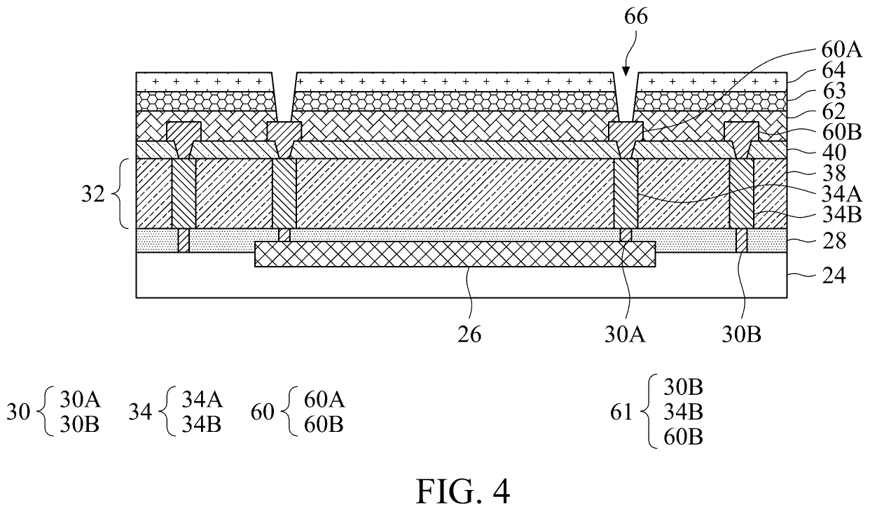

In FIG. 4, a protective layer 64 is formed on the third passivation layer 63 and openings 66 are formed through the protective layer 64, the third passivation layer 63, and the second passivation layer 62 to expose top surfaces of the active RDLs 60A. The protective layer 64 may comprise an organic dielectric material, such as polyimide, polybenzoxazole (PBO), benzocyclobutene (BCB), epoxy, or the like. The protective layer 64 may be formed by a suitable coating process, such as spin coating or the like. The openings 66 may be formed by first patterning the protective layer 64 and then etching exposed portions of the third passivation layer 63 and the second passivation layer 62. The protective layer 64 may be patterned by a suitable photolithography process. The third passivation layer 63 and the second passivation layer 62 may be etched sequentially by suitable etching processes, such as Reactive Ion Etching (RIE) or the like. The etchants may include a fluorine based compound, argon, oxygen, and nitrogen. The inactive conductive features 60B may remain covered by the second passivation layer 62 after the openings 66 are formed.

Due to configurations of the inactive conductive features 60B described above with respect to FIGS. 2A through 2G, the stress in the first passivation layer 40, the second passivation layer 62, the third passivation layer 63, and the protective layer 64 may be reduced. As a result, the formation and/or propagation of cracks and/or delamination in the first passivation layer 40, the second passivation layer 62, the third passivation layer 63, and the protective layer 64 may be prevented or reduced, thereby improving the performance and reliability of the subsequently formed semiconductor package.

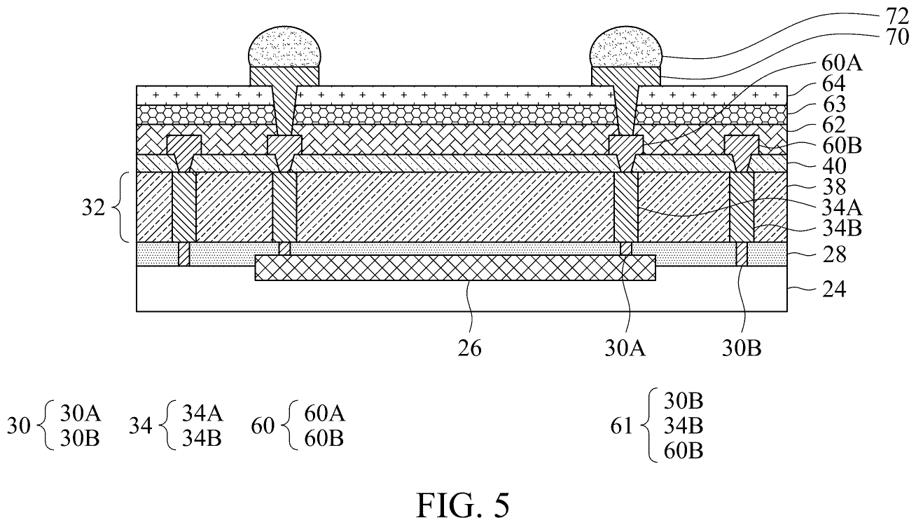

In FIG. 5, under-bump metallizations (UBMs) 70 are formed in the openings 66 and on the protective layer 64 and electrical connectors 72 are formed on the UBMs 70. The UBMs 70 have upper portions on and extending along a surface of the protective layer 64, and have lower portions extending through the protective layer 64, the third passivation layer 63, and the second passivation layer 62 to physically and electrically connect to the active RDLs 60A. As a result, the UBMs 70 are electrically connected to the devices 26. The electrical connectors 72 may be used to physically and electrically connect to external devices in subsequent processes.

The UBMs 70 may be formed by a series of processes, which are provided in the following as an example. First, a seed layer (not separately illustrated) may be formed on the protective layer 64 and in the openings 66. The seed layer may be formed using a deposition process, such as such as PVD, CVD, or the like. The seed layer may comprise a titanium layer and a copper layer over the titanium layer. Next, a patterned mask may be formed on the seed layer. The patterned mask may have openings that expose portions of the seed layer. The patterned mask may comprise photoresist or the like. A conductive material may be then formed in the openings in the patterned mask and on the exposed portions of the seed layer by a suitable plating process, such as electrochemical plating, electroless plating, or the like. The conductive material may comprise, copper, aluminum, titanium, nickel, tungsten, or the like, or alloys thereof. Next, the patterned mask may be removed by a suitable ashing process or the like and portions of the seed layer that are not covered by the conductive material may also be removed by a suitable etching process. The conductive material and the underlying portions of the seed layer may be collectively referred to as the UBMs 70.

The electrical connectors 72 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The electrical connectors 72 may include a conductive material such as solder, copper, aluminum, gold, nickel, silver, palladium, tin, the like, or a combination thereof. In some embodiments, the electrical connectors 72 are formed by initially forming a layer of solder through evaporation, electroplating, printing, solder transfer, ball placement, or the like. Once a layer of solder has been formed on the structure, a reflow may be performed in order to shape the material into the desired bump shapes. In some embodiments, the electrical connectors 72 comprise metal pillars (such as a copper pillar) formed by a sputtering, printing, electroplating, electroless plating, CVD, or the like.

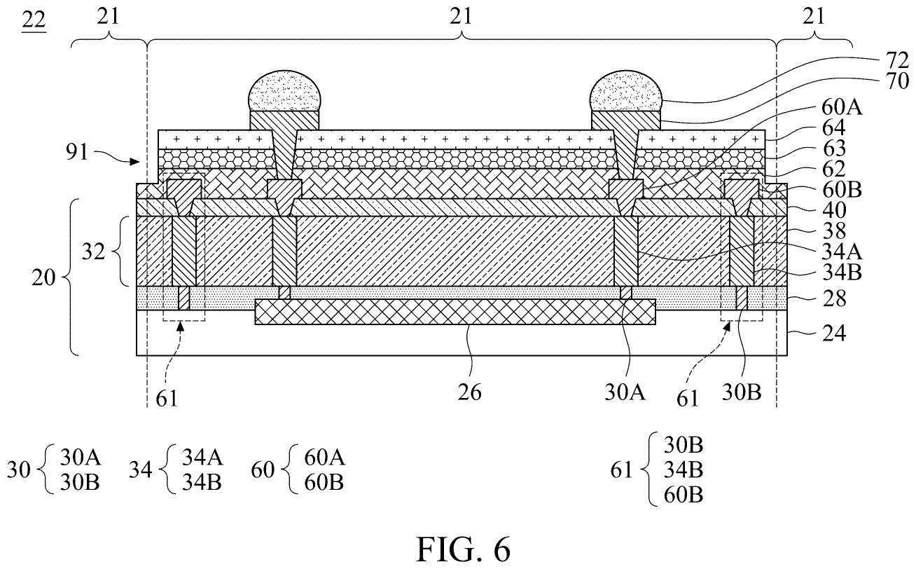

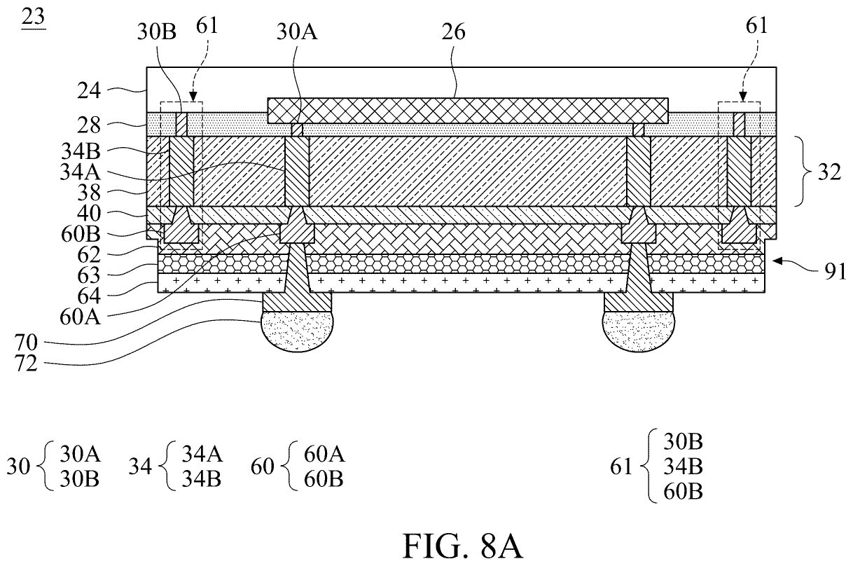

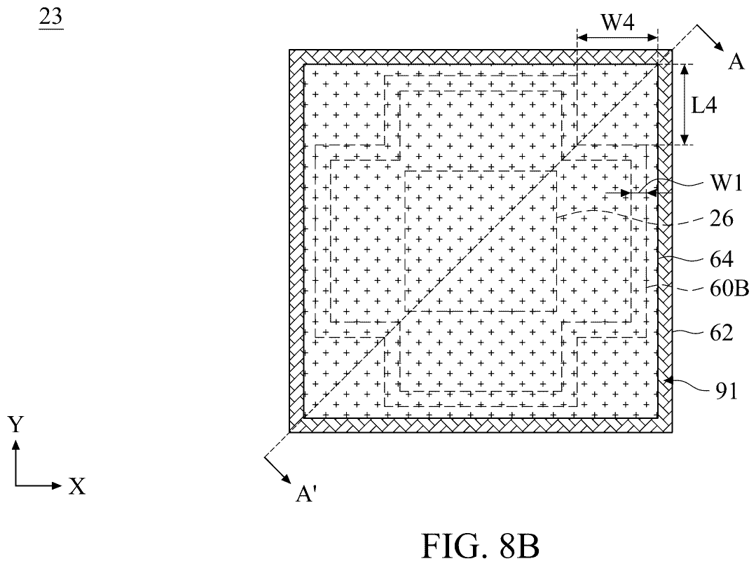

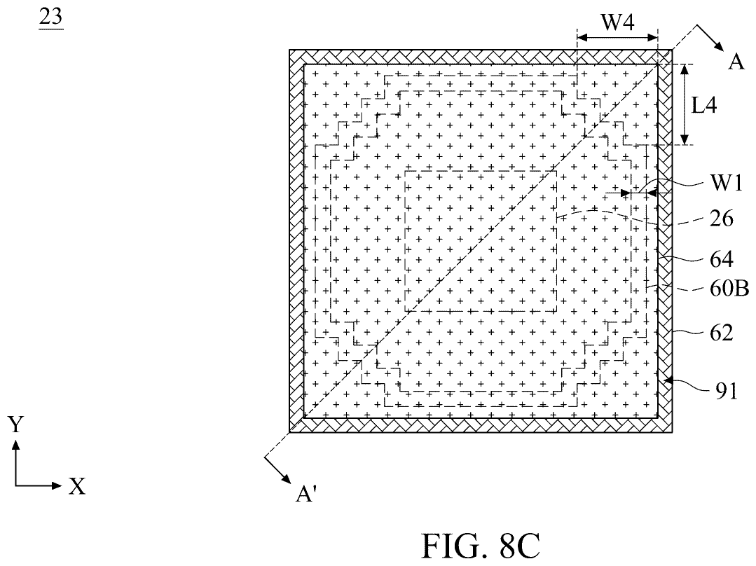

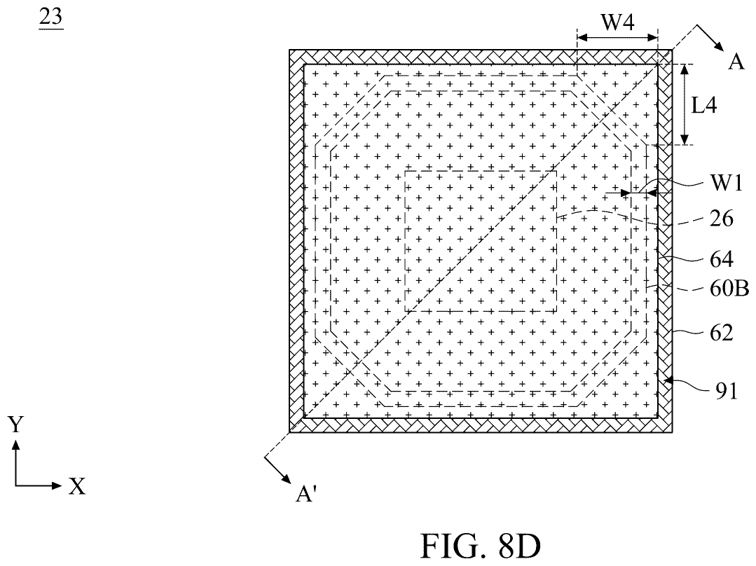

In FIG. 6, openings 91 may be formed by removing portions of the protective layer 64, the third passivation layer 63, and the second passivation layer 62. The structure shown in FIG. 6 may be referred to as a package component 22. Each opening 91 may encircle a corresponding seal ring structure 61 within a same region 21 (see FIGS. 8B, 8C, and 8D). The package component 22 may be singulated into a plurality of smaller package components in a subsequent process, each of which may correspond to a region 21. The openings 91 may provide ease to securely handling the smaller package components after the singulation process. The openings 91 may be formed by a suitable etching process, such as RIE or the like.

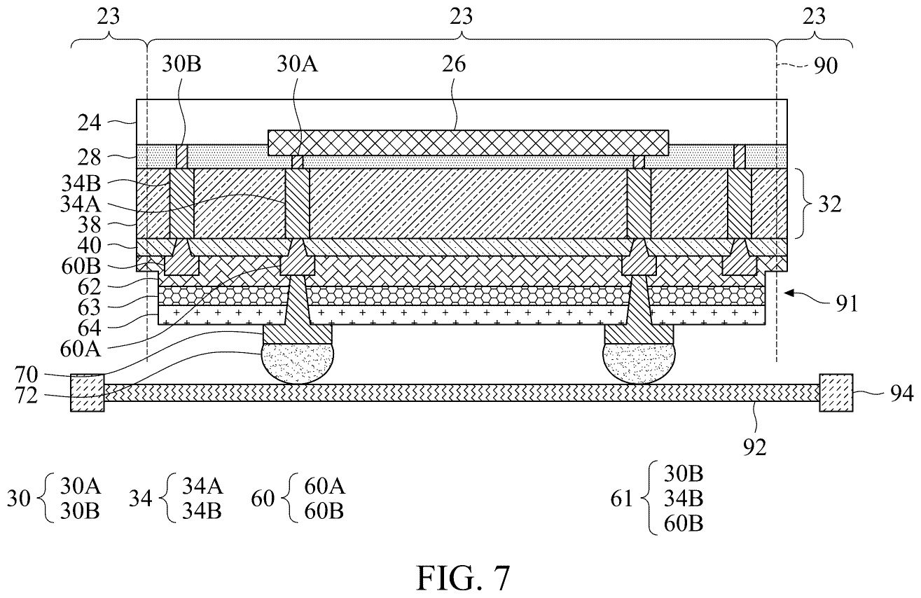

In FIG. 7, the package component 22 is singulated. The package component 22 may be placed on a tape 92 supported by a frame 94. The package component 22 may be then singulated along scribe lines 90 into smaller package component 23. Each package component 23 may correspond to a region 21 of the package component 20 (see FIG. 21). The singulation process may include a sawing process, a laser cutting process, or the like. A cleaning process or rinsing process may be performed after the singulation process.

In FIGS. 8A and 8B, the package component 23 is shown. FIG. 8A shows a cross-sectional view and FIG. 8B shows a top-down view. The cross-sectional view in FIG. 8A may be obtained along reference cross-section AA′ in the top-down view in FIG. 8B. The devices 26 and the inactive conductive feature 60B are shown in dashed lines in FIG. 2B for illustrative purposes. The seal ring structure 61, including the inactive contact plug 30B, the inactive conductive feature 34B, and the inactive conductive feature 60B, may encircle the devices 26 in the top-down view. The seal ring structure 61, including the inactive contact plug 30B, the inactive conductive feature 34B, and the inactive conductive feature 60B, may be electrically isolated from circuitry of the package component 23 and the subsequently formed semiconductor package. The seal ring structure 61 may protect the circuitry of the package component 23.

The inactive conductive feature 60B does not extend underneath corner regions of the protective layer 64, the third passivation layer 63, and the second passivation layer 62, and does not extend in the corner regions of the first passivation layer 40, which may reduce stress in the corner regions of the first passivation layer 40, the second passivation layer 62, the third passivation layer 63, and the protective layer 64. As a result, the formation of cracks and/or delamination in the first passivation layer 40, the second passivation layer 62, the third passivation layer 63, and the protective layer 64 may be prevented or reduced Each corner region of the protective layer 64 may have a width W4 and a length L4. The width W4 may be in a range from about 9.1 μm to about 88.2 μm. The length L4 may be in a range from about 9.1 μm to about 88.2 μm. Such ranges for the width W4 and the length L4 may result in sufficient reduction of stress in the corner regions of the layers mentioned above and sufficient space for the active RDLs 60A encircled by the inactive conductive feature 60B.

FIGS. 8C through 8D each illustrates a package component 23 similar to the one shown in FIG. 8B, in accordance with some embodiments, where like numerals refer to like features formed by like processes. The shape of the inactive conductive feature 60B shown in FIG. 8C may be same or similar to the shape of the inactive conductive feature 60B shown in FIG. 2C. The shape of the inactive conductive feature 60B shown in FIG. 8D may be same or similar to the shape of the inactive conductive feature 60B shown in FIG. 2D. The corner regions of the protective layer 64 may be free of the inactive conductive feature 60B underneath. Each corner region of the protective layer 64 may have a width W4 and a length L4.

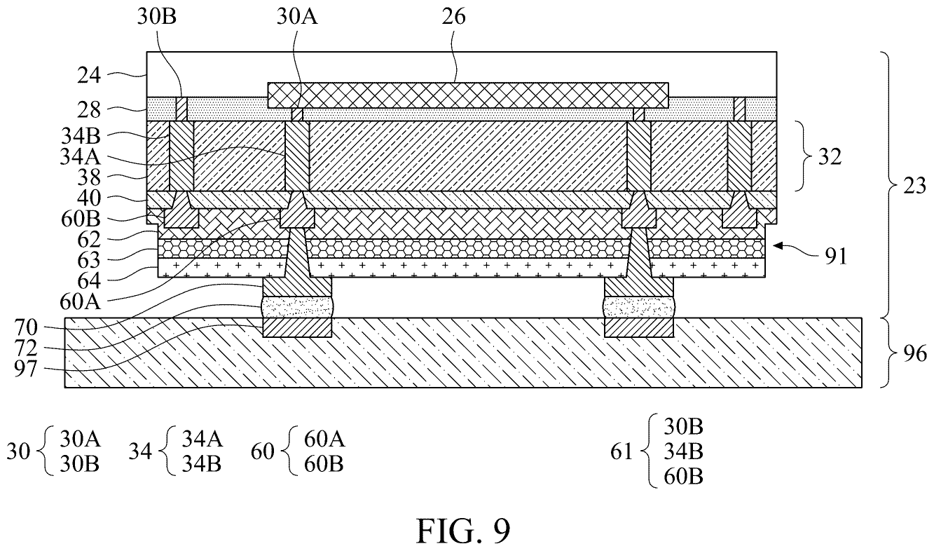

In FIG. 9, the package component 23 is bonded to a package substrate 96. The package substrate 96 may comprise conductive pads 97. In some embodiments, the package substrate 96 comprise materials, such as fiberglass reinforced resin, bismaleimide-triazine (BT) resin, or the like. In some embodiments, the package substrate 96 comprise materials such as silicon, germanium, silicon germanium, silicon carbide, gallium arsenic, indium arsenide, indium phosphide, silicon germanium carbide, gallium arsenic phosphide, gallium indium phosphide, or the like.

The package substrate 96 may include active and passive devices (not separately illustrated), such as transistors, capacitors, resistors, combinations thereof, or the like. The devices may be formed using any suitable methods. The package substrate 96 may comprise layers of dielectric material and metal lines and vias (not separately illustrated) in the layers of dielectric material. The metal lines and vias may be physically and electrically connected to the conductive pads 97 and the active and passive devices. In some embodiments, the package substrate 96 is free of active and passive devices.

During the bonding process the electrical connectors 72 may be reflowed to bond the package component 23 to the conductive pads 97. The electrical connectors 72 may electrically and physically connect the package substrate 96 to the package component 23 to form functional circuitry of the subsequently formed semiconductor package. In some embodiments, a solder resist (not separately illustrated) is on a surface of the package substrate 96 that faces the package component 23. The electrical connectors 72 may be disposed in openings in the solder resist to contact the conductive pads 97. The solder resist may be used to protect the package substrate 96 from external damages.

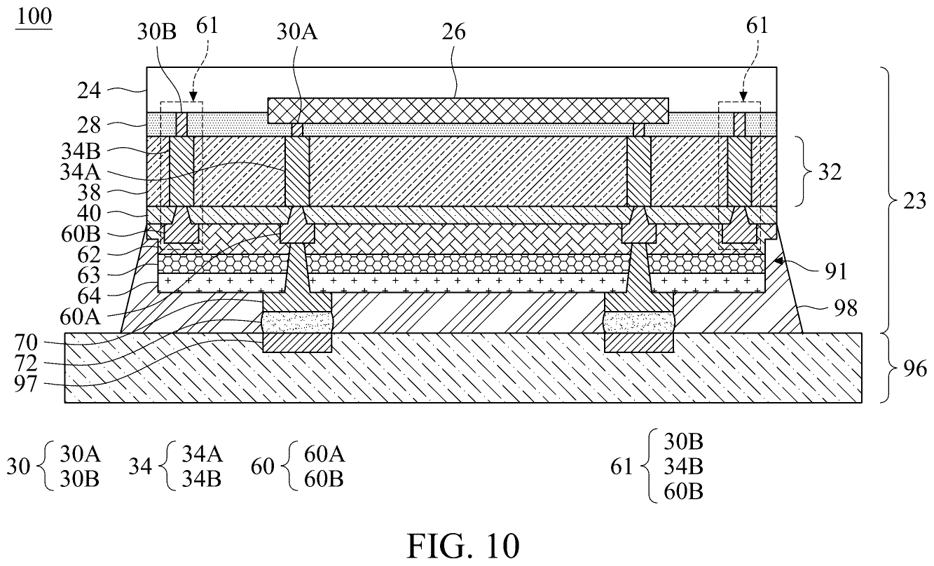

In FIG. 10, an underfill 98 is formed between the package component 23 and the package substrate 96. The resulting structure may be referred to as a semiconductor package 100. The underfill 98 may surround the electrical connectors 72 and reduce stress in the electrical connectors 72. In some embodiments, the underfill 98 fills in the openings 91, extends on sidewalls of the protective layer 64, the third passivation layer 63, and the second passivation layer 62, and extends on a bottom surface of an overhang of the second passivation layer 62. The underfill 98 may comprise a polymer material, such as epoxy or the like. The underfill 98 may be formed by a capillary flow process after the package component 23 is attached, or may be formed by a suitable deposition method before the package component 23 is attached. The underfill 98 may be subsequently cured.

The embodiments of the present disclosure have some advantageous features. Due to the various configurations of the inactive conductive features 60B described above, the stress in the first passivation layer 40, the second passivation layer 62, the third passivation layer 63, and the protective layer 64 may be reduced. As a result, the formation and/or propagation of cracks and/or delamination in the first passivation layer 40, the second passivation layer 62, the third passivation layer 63, and the protective layer 64 may be prevented or reduced, thereby improving the performance and reliability of the semiconductor package 100.

In an embodiment, a semiconductor package includes a package component including: a semiconductor substrate; a plurality of electrical devices on the substrate; a plurality of dielectric layers over the substrate and the electrical devices; a first passivation layer on the plurality of dielectric layers; a seal ring structure including: a first ring structure in the first passivation layer, wherein the first ring structure encircles the plurality of electrical devices in a top-down view, wherein the first ring structure includes a plurality of bends adjacent a first corner of the package component in the top-down view; and a second ring structure in the plurality of dielectric layers, wherein the second ring structure is in contact with the first ring structure, and wherein the second ring structure encircles the plurality of electrical devices in the top-down view; and a package substrate bonded to the package component. In an embodiment, the first ring structure has a rectangular shape with at least one notched corner adjacent the first corner of the package component in the top-down view, wherein the at least one notched corner includes a right angle. In an embodiment, the first ring structure has an octagonal shape with at least one stair-shaped segment adjacent the first corner of the package component in the top-down view. In an embodiment, the first ring structure is a continuous ring structure in the top-down view. In an embodiment, the first ring structure is a fragmented ring structure in the top-down view. In an embodiment, first ring structure includes at least one linear break extending through the first ring structure in the top-down view. In an embodiment, first ring structure includes at least one non-linear bending break extending through the first ring structure in the top-down view. In an embodiment, first ring structure includes at least one linear break and at least one non-linear break extending through the first ring structure in the top-down view.

In an embodiment, a method of forming a semiconductor package includes depositing a plurality of dielectric layers over a plurality of electrical devices on a semiconductor substrate; forming a first ring structure in the plurality of dielectric layers; depositing a first passivation layer on the plurality of dielectric layers and the first ring structure; forming a second ring structure extending through the first passivation layer to contact the first ring structure, wherein the second ring structure encircles the plurality of electrical devices in a top-down view, wherein the second ring structure includes two or more bends adjacent a first corner of the first passivation layer in the top-down view; and depositing a second passivation layer on the second ring structure and the first passivation layer. In an embodiment, the second ring structure has a rectangular shape with four notched corners having right angles in the top-down view. In an embodiment, the second ring structure has an octagonal shape with straight segments and bending segments arranged in an alternating pattern in the top-down view. In an embodiment, the second ring structure is a fragmented ring structure in the top-down view, and wherein second ring structure includes at least one Z-shaped break extending through the second ring structure in the top-down view. In an embodiment, a lower surface of the second ring structure is in contact with the first passivation layer and an upper surface of the second ring structure is in contact with the second passivation layer. In an embodiment, the second passivation layer has a level top surface.

In an embodiment, a method of forming a semiconductor package includes depositing a plurality of dielectric layers over a semiconductor substrate and a plurality of electrical devices; forming a first ring structure in the plurality of dielectric layers, wherein the first ring structure encircles the plurality of electrical devices in a top-down view; depositing a first passivation layer on the plurality of dielectric layers and the first ring structure, wherein the first passivation layer includes a first dielectric material; forming a second ring structure on the first passivation layer, wherein the second ring structure extends through the first passivation layer to contact the first ring structure, wherein the second ring structure encircles the plurality of electrical devices in the top-down view, wherein the second ring structure includes a first segment and a second segment extending along intersecting edges of the first passivation layer in the top-down view, wherein the first segment and the second segment are connected by a corner segment, wherein the first segment and the corner segment form a first angle in the top-down view, and wherein the second segment and the corner segment form a second angle in the top-down view; and depositing a second passivation layer on the second ring structure and the first passivation layer, wherein the second passivation layer includes a second dielectric material different from the first dielectric material. In an embodiment, the second ring structure has a rectangular shape with four inverted corners adjacent four corners of the first passivation layer in the top-down view. In an embodiment, the second ring structure has an octagonal shape with four stair-shaped segments adjacent four corners of the first passivation layer in the top-down view, wherein the four stair-shaped segments include the corner segment. In an embodiment, the second ring structure is a fragmented ring structure in the top-down view, wherein the second ring structure includes at least one bending break extending through the second ring structure in the top-down view, and wherein the bending break includes at least two bends. In an embodiment, the bending break is filled by the first dielectric material and the second dielectric material. In an embodiment, the second passivation layer completely covers a top surface of the second ring structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package comprising:
a package component comprising:
a semiconductor substrate;
a plurality of electrical devices on the substrate;
a plurality of dielectric layers over the substrate and the electrical devices;
a first passivation layer on the plurality of dielectric layers;
a seal ring structure comprising:
a first ring structure in the first passivation layer, wherein the first ring structure encircles the plurality of electrical devices in a top-down view, wherein the first ring structure comprises a plurality of bends adjacent a first corner of the package component in the top-down view; and
a second ring structure in the plurality of dielectric layers, wherein the second ring structure is in contact with the first ring structure, and wherein the second ring structure encircles the plurality of electrical devices in the top-down view; and
a package substrate bonded to the package component.

2. The semiconductor package of claim 1, wherein the first ring structure has a rectangular shape with at least one notched corner adjacent the first corner of the package component in the top-down view, wherein the at least one notched corner comprises a right angle.

3. The semiconductor package of claim 1, wherein the first ring structure has an octagonal shape with at least one stair-shaped segment adjacent the first corner of the package component in the top-down view.

4. The semiconductor package of claim 1, wherein the first ring structure is a continuous ring structure in the top-down view.

5. The semiconductor package of claim 1, wherein the first ring structure is a fragmented ring structure in the top-down view.

6. The semiconductor package of claim 5, wherein first ring structure comprises at least one linear break extending through the first ring structure in the top-down view.

7. The semiconductor package of claim 5, wherein first ring structure comprises at least one non-linear bending break extending through the first ring structure in the top-down view.

8. The semiconductor package of claim 5, wherein first ring structure comprises at least one linear break and at least one non-linear break extending through the first ring structure in the top-down view.

9. A method of forming a semiconductor package, the method comprising:
depositing a plurality of dielectric layers over a plurality of electrical devices on a semiconductor substrate;
forming a first ring structure in the plurality of dielectric layers;
depositing a first passivation layer on the plurality of dielectric layers and the first ring structure;
forming a second ring structure extending through the first passivation layer to contact the first ring structure, wherein the second ring structure encircles the plurality of electrical devices in a top-down view, wherein the second ring structure comprises two or more bends adjacent a first corner of the first passivation layer in the top-down view; and
depositing a second passivation layer on the second ring structure and the first passivation layer.

10. The method of claim 9, wherein the second ring structure has a rectangular shape with four notched corners having right angles in the top-down view.

11. The method of claim 9, wherein the second ring structure has an octagonal shape with straight segments and bending segments arranged in an alternating pattern in the top-down view.

12. The method of claim 9, wherein the second ring structure is a fragmented ring structure in the top-down view, and wherein second ring structure comprises at least one Z-shaped break extending through the second ring structure in the top-down view.

13. The method of claim 9, wherein a lower surface of the second ring structure is in contact with the first passivation layer and an upper surface of the second ring structure is in contact with the second passivation layer.

14. The method of claim 9, wherein the second passivation layer has a level top surface.

15. A method of forming a semiconductor package, the method comprising:
depositing a plurality of dielectric layers over a semiconductor substrate and a plurality of electrical devices;
forming a first ring structure in the plurality of dielectric layers, wherein the first ring structure encircles the plurality of electrical devices in a top-down view;
depositing a first passivation layer on the plurality of dielectric layers and the first ring structure, wherein the first passivation layer comprises a first dielectric material;
forming a second ring structure on the first passivation layer, wherein the second ring structure extends through the first passivation layer to contact the first ring structure, wherein the second ring structure encircles the plurality of electrical devices in the top-down view, wherein the second ring structure comprises a first segment and a second segment extending along intersecting edges of the first passivation layer in the top-down view, wherein the first segment and the second segment are connected by a corner segment, wherein the first segment and the corner segment form a first angle in the top-down view, and wherein the second segment and the corner segment form a second angle in the top-down view; and
depositing a second passivation layer on the second ring structure and the first passivation layer, wherein the second passivation layer comprises a second dielectric material different from the first dielectric material.

16. The method of claim 15, wherein the second ring structure has a rectangular shape with four inverted corners adjacent four corners of the first passivation layer in the top-down view.

17. The method of claim 15, wherein the second ring structure has an octagonal shape with four stair-shaped segments adjacent four corners of the first passivation layer in the top-down view, wherein the four stair-shaped segments comprise the corner segment.

18. The method of claim 15, wherein the second ring structure is a fragmented ring structure in the top-down view, wherein the second ring structure comprises at least one bending break extending through the second ring structure in the top-down view, and wherein the bending break comprises at least two bends.

19. The method of claim 18, wherein the bending break is filled by the first dielectric material and the second dielectric material.

20. The method of claim 15, wherein the second passivation layer completely covers a top surface of the second ring structure.
